(19) United States
(12) Patent Application Publication
(10) Pub. No.: US 2022/0352047 A1
(43) Pub. Date: Nov. 3, 2022

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Antonio BELLIZZI, Milano (IT); Antonio CANNAVACCIUOLO, Milan (IT)

(73) Assignee: STMicroelectronics S.r.l., Agrate Brianza (MB) (IT)

(21) Appl. No.: 17/728,298

(22) Filed: Apr. 25, 2022

(30) Foreign Application Priority Data
Apr. 28, 2021 (IT) 102021000010760

(51) Int. Cl. H01L 23/31; H01L 21/56

(52) U.S. Cl. CPC H01L 23/3135; H01L 21/56; H01L 23/3121; H01L 23/495

(57) ABSTRACT

A semiconductor device, such as a QFN (Quad-Flat No-lead) package, includes an insulating encapsulation of a semiconductor chip. The insulating encapsulation is formed by a first encapsulation material which encapsulates the semiconductor chip and a second encapsulation material that is molded onto an upper surface of the first encapsulation material. The first encapsulation material includes an oblique cavity extending from the upper surface. The second encapsulation material includes an anchoring protrusion that enters into the cavity.

### PRIORITY CLAIM

This application claims the priority benefit of Italian Application for Patent No. 102021000010760, filed on Apr. 28, 2021, the content of which is hereby incorporated by reference in its entirety to the maximum extent allowable by law.

### TECHNICAL FIELD

The description relates to semiconductor devices.

One or more embodiments can be applied advantageously, yet not exclusively, to semiconductor devices in a Quad-Flat No-lead (QFN) package.

### BACKGROUND

In various technologies applied in manufacturing semiconductor devices an interface may be created between different package materials.

For instance, Direct Copper Interconnect (DCI) technology may involve creating an interface between different package materials such as a laser direct structuring (LDS) material and a conventional molding compound such as an epoxy resin.

This involves creating smooth and flat (low-roughness) resin surfaces in order to facilitate creating homogeneous metal (e.g., copper) interconnections.

So-called pre-molded leadframes are another context where an interface is created between different package materials, namely a pre-mold material molded onto an etched (metal) leadframe structure to fill empty spaces therein and an encapsulating material is molded onto the pre-molded leadframe where one or more semiconductor chips or dice have been attached in order to complete the device package.

Mutual adhesion at the interface between different resin layers primarily depends on chemical interaction between the two materials.

A conventional way to improve resin-to-resin adhesion may involve material selection (for instance, choosing resins with high chemical compatibility and/or low water absorption) and/or material processing (for instance, increasing surface roughness).

Adopting materials “tuned” to give acceptable adhesion may be expensive and militate against adoption in large-scale manufacturing of semiconductor devices using technologies such as Direct Copper Interconnect (DCI).

A relevant factor in that respect may lie in that the possible choice of materials (resins) adequately complying with desired adhesion specifications is limited.

Delamination problems may arise if material processing is not controlled adequately. Also, while exhibiting acceptable adhesion performance, certain materials may exhibit poor “laserability” and “platability” in use as an LDS material.

There is a need in the art to contribute in addressing the issues discussed in the foregoing.

### SUMMARY

One or more embodiments may relate to a method.

One or more embodiments may relate to a corresponding semiconductor product.

One or more embodiments may provide efficient mold-to-mold (resin-to-resin) anchoring based on tilted cavities (blind holes) drilled, via laser ablation, for instance, possibly using a tilted chuck in a laser processing tool.

One or more embodiments may provide firm interlocking of different materials such as resins used for LDS molding and/or in pre-molded leadframes with standard package molding compounds (epoxy resins, for instance).

### BRIEF DESCRIPTION OF THE DRAWINGS

One or more embodiments will now be described, by way of example only, with reference to the annexed figures, wherein:

FIG. 1 is a cross-sectional view across part of a conventional semiconductor device,

FIG. 2 is a corresponding sectional view across a semiconductor product as per embodiments of the present description,

FIGS. 3 and 4 are illustrative of possible steps or acts in embodiments of the present description, and

FIG. 5 is illustrative of possible details of embodiments of the present description.

It will be appreciated that, for the sake of simplicity and ease of explanation, the various figures may not be drawn to a same scale.

Also, unless the context indicates otherwise, like parts or elements are indicated throughout the figures with like references symbols, and a detailed description will not be repeated for each and every figure for brevity.

### DETAILED DESCRIPTION

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular conformations, structures, or characteristics may be combined in any adequate way in one or more embodiments.

The headings/references used herein are provided merely for convenience and hence do not define the extent of protection or the scope of the embodiments.

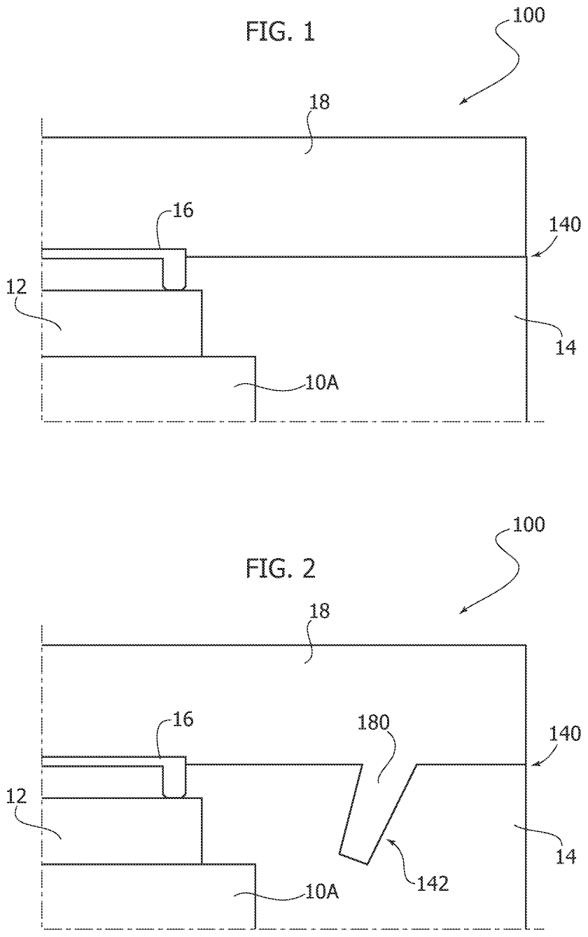

FIG. 1 is a cross-sectional view across part of a semiconductor device 100 such as, for instance, a semiconductor device in a Quad-flat No-lead (QFN) package (not visible in its entirety).

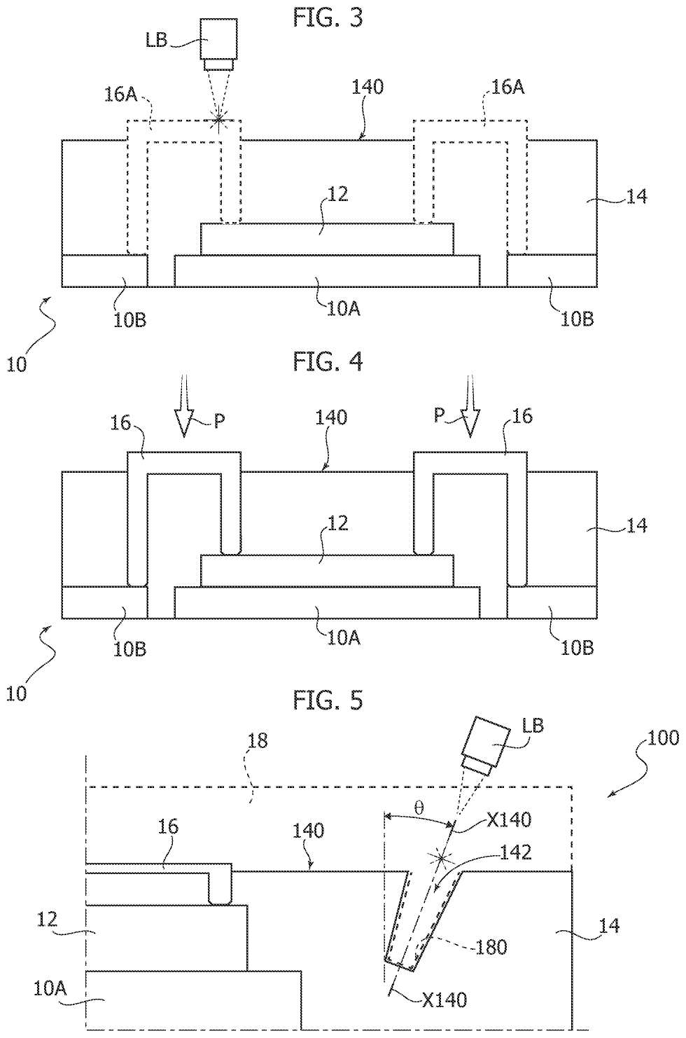

As conventional in the art, the device 100 may include a leadframe 10 (indicated as such only in FIGS. 3 and 4), comprising a die pad 10A surrounded by an array of leads 10B.

The designation leadframe (or lead frame) is currently used (see, for instance, the USPC Consolidated Glossary of the United States Patent and Trademark Office) to indicate a metal frame which provides support for a semiconductor chip or die as well as electrical leads to couple the semiconductor chip or die to other electrical components or contacts.

In the figures, reference 12 denotes a semiconductor chip or die mounted (attached) onto a die pad 10A in the leadframe 10. This may be via die attach material (not visible in the figures for simplicity).

A (first) molding compound 14 is molded onto the semiconductor chip or die 12 attached onto the die pad 10A to provide an insulating encapsulation. In an embodiment, the molding compound may comprise a laser direct structuring (LDS) material.

Electrically-conductive formations 16 for the semiconductor chip 12 are then formed by laser processing (for example, structured using LDS processing techniques) and plating metal material (e.g., copper) at the structured locations in the molding compound 14.

A (second) molding compound 18 (non-LDS, epoxy resin, for instance) is subsequently molded onto the first (LDS) molding compound 14 and the electrically-conductive formations 16 to complete the package.

Semiconductor product manufacturing technology as discussed in the foregoing is known to those of skill in the art, which makes it unnecessary to provide a more detailed description herein.

For instance, it will be easily appreciated that the molding compounds (“resins”) 14 and 18, once molded, are intended to be solidified or hardened via curing (heat and/or UV curing, for instance) to provide a rigid device package.

Technology as discussed in the foregoing is exemplary of various technologies used in manufacturing semiconductor devices where smooth and flat (low-roughness) surfaces are formed at interfaces between different materials, in order to facilitate achieving homogeneous interconnection, for instance, between the electrically-conductive formations 16 and the molding material 14.

The interface between the LDS material 14 and the non-LDS material 18 designated at reference 140 is exemplary of such a surface.

Those of skill in the art will appreciate that similar “resin-to-resin” interfaces may be produced in various other technologies currently adopted in manufacturing semiconductor devices.

In one possible example, already mentioned in the introductory portion of this description, so-called pre-molded leadframes may include a first “pre-mold” material (resin) molded onto an etched (metal) leadframe structure to fill empty spaces therein with the device package completed with an insulating encapsulation of a second mold material molded onto the pre-molded leadframe where one or more semiconductor chips or dice have been attached.

Arrangements as discussed herein (LDS or pre-molded leadframe technologies) are thus generally exemplary of methods involving providing an insulating encapsulation (such as 14 and 18 in FIG. 1) of at least one semiconductor chip (such as 12), wherein the encapsulation comprises: a first encapsulation material (14, for instance), and a second encapsulation material (18, for instance) molded onto a surface of the first encapsulation material (for instance, at the surface of the first encapsulation material defining the interface 140).

Whatever the specific arrangement involved, adhesion at the interface between different materials such as the materials 14 and 180 in FIG. 1 depends on chemical interaction between the two materials.

As noted, firm adhesion between such materials is desirable in semiconductor products (such as QFN packages, for instance) with the aim of countering undesired delamination at the interface therebetween.

As discussed in the introduction of this description, various approaches experimented in achieving such firm adhesion (resins with a high chemical compatibility and/or low water absorption or increased surface roughness) were found to be inadequate or unduly expensive in achieving a desirable degree of adhesion and in countering delamination.

One or more embodiments as exemplified in FIG. 2 address that issue by facilitating mechanical interlock between the materials 14 and 18.

This can be obtained by drilling cavities (blind holes) 142 into the (first) material 14,

The (second) material 18 can then be molded (in a flowable state) to create protruding tooth-like formations 180 of the material 18 extending into the cavities 142 in the (first) material 14.

As a result of solidification of the materials (e.g., via heat or UV curing, as conventional in the art), the protruding tooth-like formations 180 of the material 18 provide anchoring formations with undercut which facilitate mechanical interlock (in addition to chemical bonding) between the materials 14 and 18.

It is noted that causing a resin encapsulant to enter into recesses in a complementary part in a semiconductor device to facilitate a more effectively enhanced adhesion level between the two is known per se, as witnessed, for instance, by United States Patent Application Publication No. 2006/0255438 (incorporated herein by reference).

Briefly, as illustrated herein:

(A) prior to molding the encapsulation material 18 onto the surface 140 of the first encapsulation material 14, one or more cavities 142 are provided (formed by drilling, for instance) into the first material 14 at the surface 140; and

(B) the second encapsulation material 18 is then molded onto the surface 140 of the first encapsulation material 14 having at least one cavity 142 drilled therein.

In that way, the second encapsulation material 18 (in a molten, flowable state as current in molding) enters, that is, penetrates into the cavity or cavities 142 forming therein (once solidified) one or more anchoring protrusion 180 of the second encapsulation material 18 to the first encapsulation material 14.

While even just one pair of a cavity 142 and a protrusion 180 may facilitate satisfactory mutual anchoring of the materials 14 and 18, providing plural pairs of cavities 142/protrusions 180 was found to be advantageous.

For that reason, plural cavity 142/protrusion 180 pairs are primarily referred to herein.

Advantageously, the cavities (blind formations) 142 can be produced by using laser beam energy which may be from the same laser source used for structuring lines and vias (see 16A in FIG. 3) in the material 14 to produce the electrically-conductive formations 16.

FIG. 3 is exemplary of embodiments where lines and vias are “structured” (as collectively designated 16A) in the (laser direct structing—LDS) material 14 applying laser beam energy (designated LB) to the flat (low-roughness) surface 140 of the (first) molding compound 14 having one or more semiconductor chips 12 (one is illustrated for simplicity) attached on the die pad 10A in a lead frame 10.

As conventional in current LDS technology, metal material—copper, for instance—can be grown (plated, for instance, as indicated by P in FIG. 4) at the locations 16A in the mold material 14 which have been “structured” using laser beam energy LB.

In that way electrically-conductive formations 16 can be formed between the semiconductor chip 12 and the leads 10B in the leadframe 10.

As illustrated herein, laser beam energy LB is applied to the first material 14 at selected locations 16A of the surface 140 to structure therein electrically-conductive formations for the semiconductor chip 12.

Electrically-conductive material 16 is then grown at these “laser structured” locations 16A of the surface 140 prior to molding the second encapsulation material 18 onto the surface 140 of the first encapsulation material 14 to which laser beam energy LB has been applied.

As exemplified in FIG. 5, laser beam energy (possibly from the same source LB) may be applied to the molding material 14 to form therein one or more cavities (blind holes or vias) 142 into which the (second) molding material 18—represented in dashed lines in FIG. 5—can penetrate (when flowable) to form (once solidified) the anchoring formations 180.

Advantageously, the cavities 142 are formed at an angle θ to a direction orthogonal to the interface 140 between the materials 14 and 18.

That is, the cavities 142 are formed extending in a longitudinal direction X140 (the direction of the laser beam LB) which forms an angle θ to a direction orthogonal to the interface 140 between the materials 14 and 18.

The cavities 142 are thus drilled in the first material 14 along a direction oblique with respect to the surface 140.

The cavities 142 may exhibit a tapered shape gradually narrowing in cross-section starting from the surface 140: briefly, the at least one cavity 142 drilled into the first material 14 tapers from the surface 140.

Such a shape, resulting from the mechanisms underlying the “drilling” action of the laser beam LB, was found to be particularly beneficial in facilitating firm mutual anchoring of the materials 14 and 18.

A “tilt” angle θ of between approximately 15 degrees and approximately 40 degrees was found to be adequate in order that the anchoring formations 180 may somehow “bite” into the material 14 with an increased undercut effect.

As illustrated, the cavities 142 are drilled into the first material 14 along a direction X140 which forms an angle θ of approximately 15 to approximately 40 degrees to a line perpendicular to the surface 140.

In one or more embodiments, plural cavities 142 (and, correspondingly, plural anchoring formations 180) can be provided having identical or a different tilt angles θ with respect to the direction orthogonal to the upper surface 140 of the material 14.

Also, if plural cavities 142 (and anchoring formations 180) are provided on opposite sides of a die pad 10A and a semiconductor die 12 thereon, the cavities 142/anchoring formations 180 on the opposed sides can be formed with opposed tilting angles, that is, mutually converging or mutually diverging to increase the anchoring effect of the formations 180 of the material 18 into the material 14.

As exemplified in FIGS. 2 and 5, steps as discussed in the foregoing result in a semiconductor device 100 which comprises an insulating encapsulation of at least one semiconductor chip, the encapsulation comprising a first encapsulation material 14 and a second encapsulation material 18 molded onto a surface 140 of the first encapsulation material 14.

As illustrated herein, the first encapsulation material 14 has at the surface 140 one or more cavities 142 extending into the first material 14. The second encapsulation material 18 molded (in a flowable state) onto the surface 140 of the first encapsulation material 14 having the cavity or cavities 142 therein comprises one or more anchoring protrusions 180 of the second encapsulation material 18 which penetrate into the aforesaid cavities and form (as a result of the encapsulation materials 14 and 18 being solidified) anchoring formations of the second material 18 to the first material 14.

Advantageously, in the semiconductor device 100 illustrated herein, the cavity/cavities 142 extend into the first material 14 along a direction oblique with respect to the surface 140.

Advantageously, the cavity/cavities 142 extend along a longitudinal direction X140 forming an angle θ of approximately 15 degrees to approximately 40 degrees to a line perpendicular to the surface 140 of the first material 14.

Advantageously, the cavity/cavities 142 in the first material 14 have a tapered shape which tapers starting from the surface 140 of the first material.

It is noted that, in the exemplary case of a device comprising a pre-molded lead frame (repeatedly referred to in the foregoing as exemplary of other instances of semiconductor devices to which embodiments as discussed herein may apply), the pre-mold material (“resin”) pre-molded onto the sculptured metal structure of the leadframe will be exemplary of the first encapsulation material and the standard mold compound molded onto the pre-molded leadframe having one or more semiconductor chips attached thereon will be exemplary of the second encapsulation material 14.

Also in that case (as in the case illustrated here), in the resulting semiconductor device the first encapsulation material (here, 14) will have at the surface of the pre-molded leadframe at least one cavity (like the cavity 142 here illustrated formed in the surface 140) extending into the first material (14), while the second encapsulation material (here, 18) molded onto the surface (here, 140) of the first encapsulation material (here, 14) will comprise at least one anchoring protrusion (here, 180) of the second encapsulation material 18 penetrating into said at least one cavity 142.

Without prejudice to the underlying principles, the details and embodiments may vary, even significantly, with respect to what has been described by way of example only without departing from the extent of protection.

The claims are an integral part of the technical teaching of the embodiments as provided herein.

The extent of protection is determined by the annexed claims.

1. A method, comprising:
encapsulating a semiconductor chip within a first encapsulation material having an upper surface;
forming a cavity extending into the first encapsulation material from the upper surface of the first encapsulation material along a direction that is oblique with respect to said upper surface; and
molding a second encapsulation material onto the upper surface of the first encapsulation material, wherein said second encapsulation material enters into said cavity and forms therein an anchoring protrusion of the second encapsulation material to the first encapsulation material.

2. The method of claim 1, wherein said direction forms an angle of approximately 15 to approximately 40 degrees with respect to a line perpendicular to said upper surface.

3. The method of claim 1, wherein said cavity is a blind hole.

4. The method of claim 3, wherein said blind hole has a width defined by a narrowing taper from the upper surface of the first encapsulation material to a bottom of the blind hole.

5. The method of claim 1, wherein forming the cavity comprises applying laser beam energy to the first encapsulation material at said upper surface.

6. The method of claim 1, further comprising:
applying laser beam energy to said first encapsulation material at selected locations of the upper surface to structure a plurality of electrically-conductive formations at the upper surface; and
wherein molding the second encapsulation material is performed after applying laser beam energy.

7. The method of claim 6, further comprising growing electrically-conductive material at said selected locations prior to molding the second encapsulation material.

8. A semiconductor device, comprising:
an insulating encapsulation of a semiconductor chip, the insulating encapsulation comprising a first encapsulation material encapsulating the semiconductor chip and a second encapsulation material molded onto an upper surface of the first encapsulation material, wherein:
the first encapsulation material includes a cavity extending into the first encapsulation material from the upper surface along a direction that is oblique with respect to said upper surface; and
the second encapsulation material that is molded onto said upper surface comprises an anchoring protrusion entering into said cavity.

9. The semiconductor device of claim 8, wherein said direction forms an angle of approximately 15 to approximately 40 degrees with respect to a line perpendicular to said upper surface.

10. The semiconductor device of claim 8, wherein said cavity has a width that forms a narrowing taper from the upper surface of the first encapsulation material.

11. A method, comprising:
molding a first encapsulation material over a semiconductor chip to provide an insulating encapsulation having an upper surface;
applying laser beam energy to the insulating encapsulation to form a cavity extending into the insulating encapsulation from the upper surface; and
molding a second encapsulation material onto the upper surface of the first encapsulation material, wherein said second encapsulation material fills said cavity in contact with the first encapsulation material to form an anchoring protrusion of the second encapsulation material within the insulating encapsulation.

12. The method of claim 11, wherein said cavity extends into the insulating encapsulation at an oblique angle with respect to a line perpendicular to said upper surface.

13. The method of claim 12, wherein said cavity is a blind hole.

14. The method of claim 12, wherein said cavity has a width that forms a narrowing taper from the upper surface of the first encapsulation material.

15. The method of claim 11, further comprising forming electrical connections on the upper surface of the insulating encapsulation, and wherein molding the second encapsulation material is performed after forming electrical connections.
